(19) United States
(12) Patent Application Publication
(10) Pub. No.: US 2024/0212711 A1
(43) Pub. Date: Jun. 27, 2024

(54) FILM FORMING APPARATUS

(71) Applicant: Resonac Corporation, Tokyo (JP)

(72) Inventor: Chihiro TAMURA, Chiba (JP)

(21) Appl. No.: 18/500,465

(22) Filed: Nov. 2, 2023

(30) Foreign Application Priority Data
Dec. 23, 2022 (JP) 2022-207110

(51) Int. Cl. G11B 5/84; G11B 5/012; G11B 5/725; G11B 5/82

(52) U.S. Cl. CPC G11B 5/8408; G11B 5/012; G11B 5/725; G11B 5/82

(57) ABSTRACT

A film forming apparatus includes chambers configured to perform a film forming process, a carrier configured to hold a substrate to be subjected to the film forming process in the chambers, and a transport mechanism configured to successively transport the carrier through the chambers. The carrier includes a support surface configured to support the carrier from below when transporting the carrier, and the support surface is provided parallel to the transport direction. The chambers include rotating members, provided parallel to the transport direction, and configured to make contact with the support surface when transporting the carrier. The rotating members are made of a magnetic material, and a magnet is provided around each of the rotating members.

### CROSS-REFERENCE TO RELATED APPLICATIONS

This application is based upon and claims priority to Japanese Patent Application No. 2022-207110, filed on Dec. 23, 2022, the entire contents of which are incorporated herein by reference.

### BACKGROUND

### 1. Field of the Invention

Certain aspects of the embodiments discussed herein are related to film forming apparatuses that perform a film forming process while successively transporting a substrate that is held by a carrier through a plurality of chambers.

### 2. Description of the Related Art

In recent years, the application range of a magnetic storage apparatus increased considerably, thereby increasing importance of the magnetic storage apparatus. On the other hand, a recording density of a magnetic recording medium used in the magnetic storage apparatus improved considerably.

An example of a method for manufacturing the magnetic recording medium successively forms a soft magnetic layer, an intermediate layer, a recording magnetic layer, or the like on a nonmagnetic substrate, and then forms a protective layer on the recording magnetic layer or the like.

In the case of such a manufacturing method, a film forming process is preferably performed continuously using a single film forming apparatus as much as possible, in order to prevent the substrate from becoming contaminated when handled, and to improve a productivity of the magnetic recording medium by improving an efficiency of manufacturing processes and improving a yield of the product by reducing the number of handling steps or processes, or the like.

Accordingly, in the manufacturing method for the magnetic recording medium, there is a proposal to use an in-line film forming apparatus that successively forms magnetic layers or the like on both surfaces of a plurality of nonmagnetic substrates, while successively transporting a carrier holding the plurality of nonmagnetic substrates through a plurality of chambers. For example, Japanese Laid-Open Patent

Publication No. H08-274142 proposes such an in-line film forming apparatus having a configuration in which the carrier is successively transported through a plurality of vacuum chambers arranged along a polygonal transport path. In addition, Japanese Laid-Open Patent Publication No.

2006-517324 proposes an in-line film forming apparatus having a configuration in which the carrier is successively transported through a plurality of vacuum chambers arranged along a circular transport path.

In the in-line film forming apparatus, the carrier that holds the substrate is successively transported through a plurality of chambers, to form a multilayer film on the substrate surface. A large number of rotating members are used in a carrier transport mechanism. However, there is a problem in that dust is generated at a portion where the rotating members and the carrier make contact, and the dust causes contamination of a product that is formed by the film forming process.

### SUMMARY

In view of the above problem, it is one object of the present disclosure to provide a film forming apparatus that can reduce the generation of dust at a transport mechanism.

According to one aspect of the present disclosure, there is provided a film forming apparatus including a plurality of chambers configured to perform a film forming process; a carrier configured to hold a substrate to be subjected to the film forming process in the plurality of chambers; and a transport mechanism configured to successively transport the carrier through the plurality of chambers, wherein the carrier includes a support surface configured to support the carrier from below when transporting the carrier, the support surface is provided parallel to the transport direction, the plurality of chambers include a plurality of rotating members, provided parallel to the transport direction, and configured to make contact with the support surface when transporting the carrier, the plurality of rotating members are made of a magnetic material, and a magnet is provided around each of the plurality of rotating members.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating an example of a magnetic recording medium manufactured by a film forming apparatus according to one embodiment;

FIG. 2 is a plan view illustrating a configuration of an in-line film forming apparatus according to one embodiment;

FIG. 3 is a side view of a chamber of the in-line film forming apparatus illustrated in FIG. 2;

FIG. 4 is a schematic front view of a carrier used in the in-line film forming apparatus;

FIG. 5 is a schematic side view of the carrier used in the in-line film forming apparatus;

FIG. 6 is a side view of a rotation unit for transporting the carrier;

FIG. 7 is a top view of the rotation unit;

FIG. 8 is a diagram illustrating an example of a rotation unit before attaching a magnet unit;

FIG. 9 is a diagram illustrating an example of a magnet unit having a magnet attached to a nonmagnetic material; and

FIG. 10 is a diagram illustrating another example of the magnet unit having the magnet attached to the nonmagnetic material.

### DETAILED DESCRIPTION

The present disclosure includes the following configurations.

[1] A film forming apparatus comprising:
a plurality of chambers configured to perform a film forming process;
a carrier configured to hold a substrate to be subjected to the film forming process in the plurality of chambers; and
a transport mechanism configured to successively transport the carrier through the plurality of chambers, wherein
the carrier includes a support surface configured to support the carrier from below when transporting the carrier,
the support surface is provided parallel to the transport direction,
the plurality of chambers include a plurality of rotating members, provided parallel to the transport direction, and configured to make contact with the support surface when transporting the carrier,
the plurality of rotating members are made of a magnetic material, and
a magnet is provided around each of the plurality of rotating members.

[2] The film forming apparatus according to [1 ] above, wherein an upper end of the magnet is located at a position lower than an uppermost portion of each of the plurality of rotating members by a distance corresponding to ⅓ of a diameter of each of the plurality of rotating members or greater.

[3] The film forming apparatus according to [1 ] or [2] above, further comprising:
a rotation unit provided with the plurality of rotating members arranged in a line in a direction parallel to the transport direction, and a magnet unit including the magnet.

[4] The film forming apparatus according to [3 ] above, wherein the magnet unit includes a nonmagnetic material, and one or more magnets attached to the rotation unit via the nonmagnetic material.

Hereinafter, embodiments of the present invention will be described in detail, with reference to the drawings. In order to facilitate understanding of the description, the same constituent elements or components are designated by the same reference numerals, and a redundant description thereof will be omitted. In addition, a scale of each member in the drawings may be different from the actual scale. In the present specification, a numerical range of “A to B” refers to a range including a value A as a lower limit value and a value B as an upper limit value, unless indicated otherwise.

A film forming apparatus according to one embodiment of the present invention will be described. In the present embodiment, a description will be given of a case where the film forming apparatus is an in-line film forming apparatus that performs a film forming process while successively transporting a disk shaped substrate through a plurality of chambers. In the present embodiment, a description will be given of a case where a magnetic recording medium to be provided in a hard disk device is manufactured using the in-line film forming apparatus, as an example.

### Magnetic Recording Medium

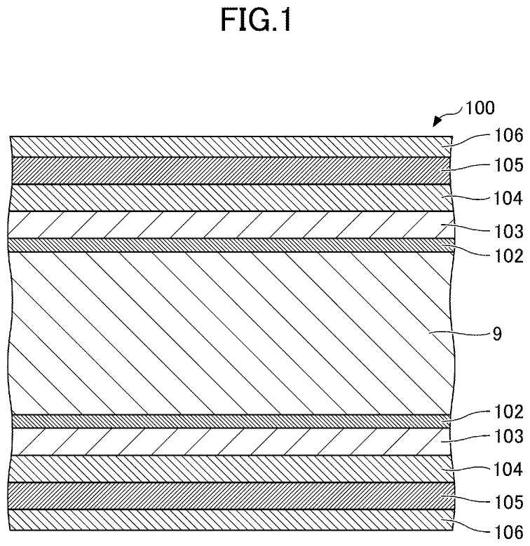

The magnetic recording medium manufactured by the film forming apparatus according to the present embodiment may be a generally known or existing magnetic recording medium. For example, as illustrated in FIG. 1, a magnetic recording medium 100 may have a structure including a soft magnetic layer 102, an intermediate layer 103, a recording magnetic layer 104, and a protective layer 105 that are successively laminated on both surfaces (that is, top and bottom surfaces) of a disk shaped substrate 9, and a lubricant film 106 formed on the outermost surfaces of the magnetic recording medium 100. The outermost surfaces include an upper surface of an upper protective layer 105, and a lower surface of a lower protective layer 105, for example.

Examples of the disk shaped substrate 9 include Al alloy substrates including Al as a main component thereof, such as Al—Mg alloys or the like, and substrates made of any one of ordinary soda glass, aluminosilicate-based glass, glass ceramics (or crystallized glass), silicon, titanium, ceramics, various resins, or the like, for example. That is, an arbitrary nonmagnetic substrate may be used for the disk shaped substrate 9.

The soft magnetic layer 102, the intermediate layer 103, the recording magnetic layer 104, the protective layer 105, and the lubricant film 160 of the magnetic recording medium 100 may be made of materials generally used for a soft magnetic layer, an intermediate layer, a recording magnetic layer, a protective layer, and a lubricant film of a known or existing magnetic recording medium, respectively.

### In-line Film Forming Apparatus

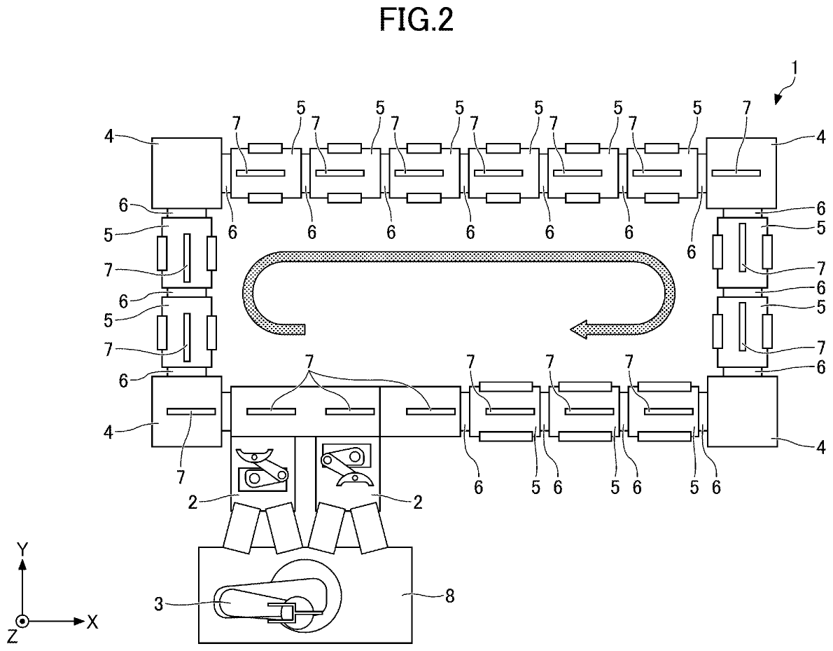

FIG. 2 is a plan view illustrating a configuration of the film forming apparatus (in-line film forming apparatus) according to the present embodiment. In FIG. 2, a three dimensional orthogonal coordinate system having three axis directions, namely, an X-axis direction, a Y-axis direction, and a Z-axis direction, is used. A length direction, a width direction, and a height direction of the in-line film forming apparatus are defined as the X-direction, the Y-direction, and the Z-direction, respectively. A direction from a bottom to a top of the in-line film forming apparatus is defined as a +Z-axis direction, and a direction opposite thereto is defined as a -Z-axis direction. When manufacturing the magnetic recording medium 100 illustrated in FIG. 1, for example, the magnetic recording medium 100 can be obtained with a high productivity by performing a step or process to successively laminate at least the soft magnetic layer 102, the intermediate layer 103, the recording magnetic layer 104, the protective layer 105, and the lubricant film 106 on both surfaces of the disk shaped substrate 9 that is a film formation target, using the film forming apparatus (in-line film forming apparatus) 1 according to the present embodiment illustrated in FIG. 2.

More particularly, an in-line film forming apparatus 1 generally includes a robot table 8, a substrate attaching and detaching robot 2 adjacent to the robot table 8, a substrate cassette transport robot 3 placed on the robot table 8, and a plurality of corner chambers 4 that are configured to rotate a carrier 7. The in-line film forming apparatus 1 further includes a plurality of chambers 5 disposed between adjacent corner chambers 4, and a plurality of carriers 7 successively transported through the plurality of corner chambers 4 and the plurality of chambers 5.

In addition, a gate valve 6 is provided at a connecting part of each chamber 5, and the inside of each chamber 5 can become an independent hermetically sealed space when the gate valves 6 at the connecting parts thereof are in a closed state.

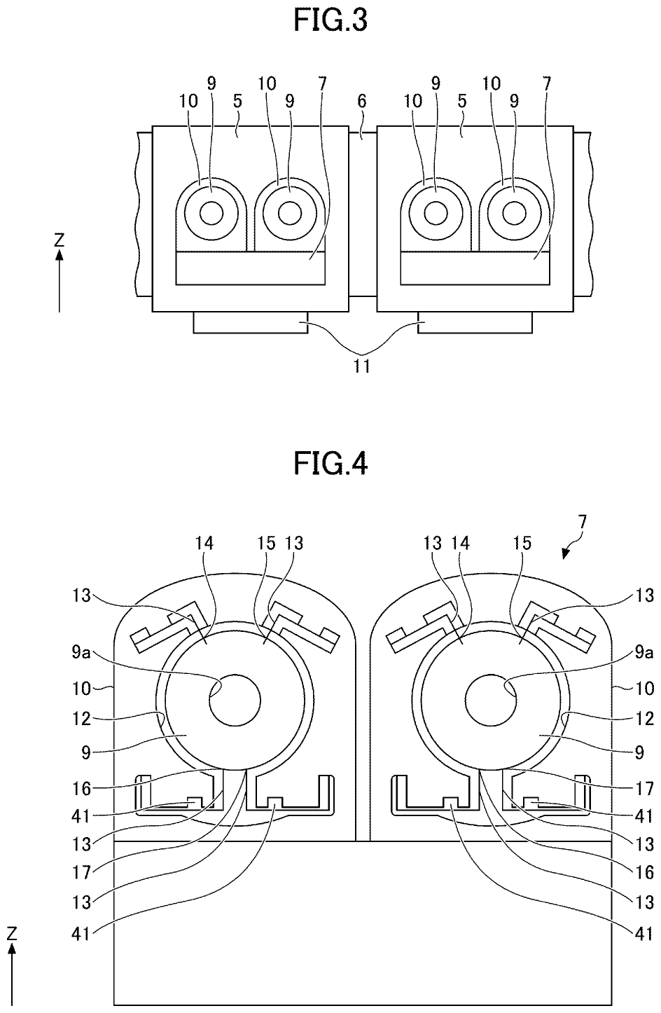

A vacuum pump (not illustrated) is connected to each chamber 5, and the inside of each chamber 5 can be controlled to a decompression state when the vacuum pump operates. The soft magnetic layer 102, the intermediate layer 103, the recording magnetic layer 104, and the protective layer 105 are successively formed on both surfaces of the disk shaped substrate 9 (not illustrated in FIG. 2 but illustrated in FIG. 3 which will be described later) that is held by the carrier 7 inside each chamber 5, while successively transporting the carrier 7 into each chamber 5 by a transport mechanism 11 (not illustrated in FIG. 2 but illustrated in FIG. 3 which will be described later). After the protective layers 105 are formed on the disk shaped substrate 9, the disk shaped substrate 9 is unloaded from the in-line film forming apparatus 1, and the lubricant film 106 is formed on both surfaces (that is, the protective layers 105) of the disk shaped substrate 9, to finally obtain the magnetic recording medium 100 illustrated in FIG. 1. The lubricant film 106 may be formed in the in-line film forming apparatus 1, as appropriate.

Each corner chamber 4 is a chamber that is configured to change a moving direction of the carrier 7, and a mechanism that is configured to rotate the carrier 7 and moving the rotated carrier 7 to an adjacent (or next) chamber 5 is provided in each corner chamber 4.

FIG. 3 is a side view of the chamber 5 of the in-line film forming apparatus 1 illustrated in FIG. 2.

The in-line film forming apparatus 1 includes a linear motor driving mechanism that drives the carrier 7 in a non-contact state (or contactless state), for example, as the transport mechanism 11 that transports the carrier 7. The linear motor driving mechanism includes a plurality of magnets that are disposed on a lower part of the carrier 7 so that north poles (N-poles) and south poles (S-poles) thereof are alternately arranged, and a rotary magnet disposed below the plurality of magnets via a partition wall along a transport direction so that N-poles and S-poles thereof are spirally and alternately arranged. The linear motor driving mechanism transports the carrier 7 by rotating the rotary magnet around an axis while magnetically coupling the magnets of the carrier 7 and the rotary magnet in the non-contact state.

FIG. 4 is a schematic front view of the carrier 7 used in the in-line film forming apparatus 1, and FIG. 5 is a schematic side view of the carrier 7 used in the in-line film forming apparatus 1. In FIG. 4 and FIG. 5, only the height direction (Z-axis direction) is illustrated. As illustrated in FIG. 4, the carrier 7 is

provided with a holder 10 that is configured to hold the disk shaped substrate 9 in a vertical position. The vertical position refers to a state where principal surfaces (top and bottom surfaces) of the disk shaped substrate 9 are parallel to a direction in which gravity acts. The holder 10 detachably holds the disk shaped substrate 9 in a hole 12 provided on an inner side of the holder 10. That is, four support members 13 are provided in a periphery of the hole 12 of the holder 10 in an elastically deformable manner. The four support members 13 make contact with end portions 14, 15, 16, and 17 of the disk shaped substrate 9, and support the disk shaped substrate 9 that is fitted into the hole 12. The end portion 14 is a left end of an upper edge of the disk shaped substrate 9, the end portion 15 is a right end of the upper edge of the disk shaped substrate 9, the end portion 16 is a left end of a lower edge of the disk shaped substrate 9, and the end portion 17 is a right end of the lower edge of the disk shaped substrate 9.

The disk shaped substrate 9 is attached to and

detached from the holder 10 by the substrate attaching and detaching robot 2 illustrated in FIG. 2. More particularly, when attaching the substrate 9 to the holder 10, the substrate attaching and detaching robot 2 inserts two release rods into two release holes 41, respectively, to push the two lower support members 13 downward. The substrate attaching and detaching robot 2 inserts a substrate holding member (not illustrated) into an opening 9a of the disk shaped substrate 9, so as to suspend the disk shaped substrate 9 from the substrate holding member. The substrate attaching and detaching robot 2 inserts the disk shaped substrate 9 that is suspended by the substrate holding member into the hole 12 of the holder 10. When the two lower support members 13 are thereafter released from being pushed downward by the two release rods, the two lower support member 13 return to original positions thereof, and as a result, the disk shaped substrate 9 is supported by the four support members 13.

When detaching the disk shaped substrate 9 from the holder 10, the substrate attaching and detaching robot 2 inserts the substrate holding member into the opening 9a of the disk shaped substrate 9 so as not to make contact with the opening 9a of the disk shaped substrate 9. Then, the two release rods are inserted into the two release holes 41, respectively, to push the two lower support members 13 downward to release the support of the disk shaped substrate 9 by the four support members 13, and the substrate attaching and detaching robot 2 suspends the disk shaped substrate 9 from the substrate holding member. The substrate attaching and detaching robot 2 detaches the disk shaped substrate 9 from the holder 10, so that the disk shaped substrate 9 does not collide with the support members 13.

As illustrated in FIG. 5, the carrier 7 is provided with a support surface 42 that is supported from below when transporting the carrier 7. The support surface 42 is formed in a rail shape extending in a direction parallel to the transport direction of the carrier 7. A cross sectional shape of the support surface 42 may be an inverted V shape or an inverted U shape, so that the rotating members 51 supporting the carrier 7 from the lower side fit into the inverted V shape or the inverted U shape of the support surface 42. FIG. 5 illustrates an example in which the cross sectional shape of the support surface is the inverted V shape. The support surface 42 extending in the direction parallel to the transport direction of the carrier 7 is not limited to the support surface 42 extending in a direction perfectly parallel to the transport direction, and may include the support surface 42 extending in a direction approximately parallel to the transport direction or generally in the same direction as the transport direction.

A linear motor driving unit 43, having a plurality of magnets so that N-poles and S-poles thereof are alternately arranged, is provided on the lower part of the carrier 7, as a part of the linear motor driving mechanism.

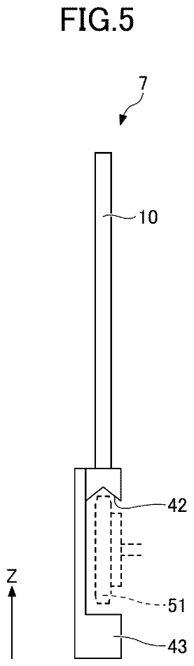

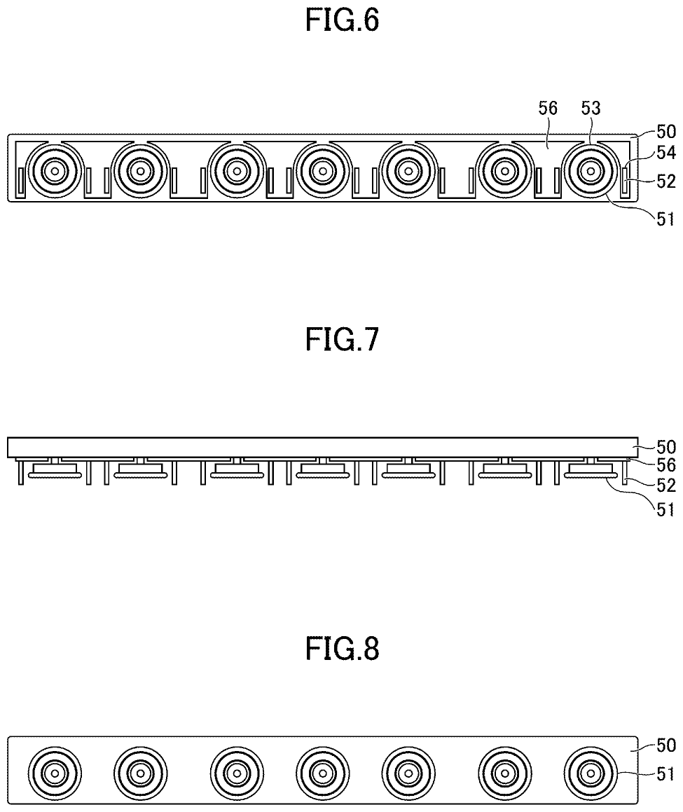

FIG. 6 is a side view of a rotation unit 50 for transporting the carrier 7, and FIG. 7 is a top view of the rotation unit 50. As illustrated in FIG. 6 and FIG. 7, the rotation unit 50 is provided in the plurality of chambers 5 illustrated in FIG. 2 and FIG. 3, so that the rotating members 51 are arranged in a line along the transport direction of the carrier 7. As illustrated in FIG. 2 and FIG. 3, because the gate valve 6 is provided at the connecting part of each chamber 5, the rotation unit 50 is not provided at the position of the gate valve 6 so that each gate valve 6 can be opened and closed.

The rotation unit 50 is provided with a plurality of rotating members 51 (seven rotating members 51 in FIG. 6 and FIG. 7), which are arranged in a line in the direction parallel to the transport direction, and make contact with the support surface 42 when transporting the carrier 7. The rotating members 51 are made of a magnetic material. By disposing magnets 52 in the rotation unit 50 around the rotating member 51, dust generated due to friction between the rotating member 51 and the support surface 42 (refer to FIG. 5) can be attracted to and collected by the magnets 52. Hence, the magnets 52 can effectively eliminate a source of the contamination of the product that is subjected to the film forming process.

Examples of the magnetic material that can be used for the rotating member 51 include Fe, Ni, Co, Fe-based alloys, Ni-based alloys, and Co-based alloys. An example of the Fe-based alloys includes stainless steel.

An upper end 54 of the magnet 52 is preferably located at a position lower than an uppermost portion 53 of the rotating member 51, that is, the position where the rotating member 51 makes contact with the support surface 42 of the carrier 7, within a range of ⅓ to ⅔, more preferably within a range of ½ to ⅔ of a diameter of the rotating member 51. In FIG. 6, the upper end 54 of the magnet 52 is located at a position lower than the uppermost portion 53 of the rotating member 51 by a distance corresponding to ½ of the diameter of the rotating member 51.

The upper end 54 of the magnet 52 is located at the position lower than the uppermost portion 53 of the rotating member 51 by a distance corresponding to ⅓ of the diameter of the rotating member 51 or greater, that is, the magnet 52 is located at the position farther away from the position where the rotating member 51 makes contact with the support surface 42 of the carrier 7 (refer to FIG. 2 and FIG. 3). Hence, the dust generated from the rotating member 51 can be collected efficiently, and the dust collected by the magnet 52 can be prevented from being scattered again as dust into the space due to the vibration of the contact portion of the rotating member 51. On the other hand, when the upper end 54 of the magnet 52 is located at a position higher than a lowermost portion of the rotating member 51 by a distance corresponding to ⅓ of the diameter of the rotating member 51 or greater, it is possible to improve the dust collecting capability of the magnet 52.

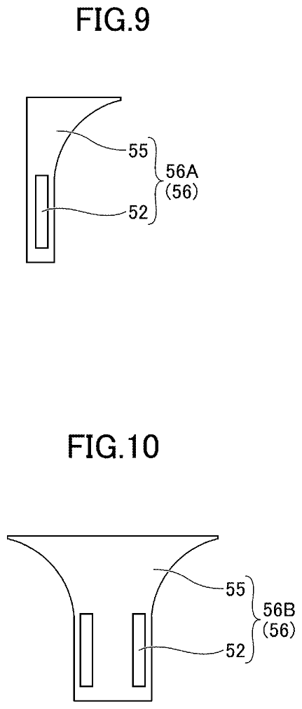

The magnet 52 is preferably attached to the rotation unit 50 via a nonmagnetic material 55. FIG. 8 illustrates an example of the rotation unit 50 before a magnet unit 56 is attached thereto, and FIG. 9 and FIG. 10 illustrate an example of the magnet unit 56 having one or more magnets 52 attached to the nonmagnetic material 55. The magnet unit 56 illustrated in FIG. 9 or FIG. 10 may be attached to the rotation unit 50. That is, the magnet unit 56 may be a magnet unit 56A having one magnet 52 attached to the nonmagnetic material 55 as illustrated in FIG. 9, or a magnet unit 56B having two magnets 52 attached to the nonmagnetic material 55 as illustrated in FIG. 10. Further, the magnet unit 56 may be a magnet unit having three or more magnets 52 attached to the nonmagnetic material 55.

Because the magnet unit 56 illustrated in FIG. 9 or FIG. 10 is attached to the rotation unit 50, the structure inside the chamber 5 is less likely to be magnetized by a magnetic field generated by the magnet 52. For this reason, the dust is prevented from being attracted near the contact position between the rotating member 51 and the carrier 7, thereby preventing the attracted dust from being scattered again as dust due to the vibration when the carrier 7 is transported. Moreover, because the magnet 52 attached to the nonmagnetic material 55 is formed as one unit, the magnet 52 can easily be attached and detached when cleaning the magnet 52.

Aluminum alloys, chromium alloys, molybdenum alloys, tungsten alloys, or the like can be used for the nonmagnetic material 55.

As described above, the in-line film forming apparatus 1 includes the plurality of chambers 5, the carrier 7, and the transport mechanism 11. In the in-line film forming apparatus 1, the carrier 7 is provided with the support surface 42 that is supported from below when transporting the carrier 7, and the support surface 42 is provided parallel to the transport direction. The in-line film forming apparatus 1 includes the plurality of rotating members 51 provided parallel to the transport direction and making contact with the support surface 42 when transporting the carrier 7, inside the plurality of chambers 5. The rotating members 51 are made of a magnetic material, and the magnets 52 are disposed around the rotating member 51. In the in-line film forming apparatus 1, because the dust generated due to friction between the rotating member 51 and the support surface 42 can be collected by the magnet 52, it is possible to reduce the generation of dust in the transport mechanism 11.

Accordingly, in the in-line film forming apparatus 1, because the source of contamination of the product that is subjected to the film forming process can be effectively eliminated, the contamination of the product due to the dust can be reduced, and the yield of the product can be improved.

While certain embodiments are described above, the embodiments are presented as examples only, and are not intended to limit the scope of the present invention. The embodiments described above can be implemented in various other forms, and various combinations, omissions, substitutions, modifications, or the like can be made without departing from the scope of the invention. The present invention is not limited to the embodiments and modifications thereof, and is intended to include what is defined in the claims, and all modifications within the meaning and scope equivalent to the scope of claims.

### EXEMPLARY IMPLEMENTATIONS

Hereinafter, the embodiments will be

specifically described with reference to exemplary implementations and comparative examples, but the embodiments are not limited to these exemplary implementations and comparative examples.

### Exemplary Implementation EI1

The in-line film forming apparatus 1 having the configuration illustrated in FIG. 1 was prepared as an exemplary implementation EI1. Stainless steel (SUS304) was used for the support surface of the carrier and the rotating members, samarium-cobalt was used for the magnet, and an aluminum alloy was used for the nonmagnetic material for attaching the magnet. The upper end of the magnet was located at a position lower than the uppermost portion of the rotating member by a distance corresponding to ½ of the diameter of the rotating member. A transport speed of the carrier through the chambers was 1.2 m/sec, and an acceleration when increasing or decreasing the transport speed was 6 m/sec2. Using the prepared in-line film forming apparatus 1, an amount of particles of the dust generated inside the chamber was measured by a particle monitor as an amount of dust. Measurement results for the exemplary implementation EI1 are illustrated in Table 1. In Table 1, “contact position” refers to the position where the rotating member 51 makes contact with the support surface 42 of the carrier 7.

### Exemplary Implementations EI2 through EI4, and Comparative Example CE1

The in-line film forming apparatus 1 was prepared as exemplary implementations EI2 through EI4 and a comparative example CE1, similar to the exemplary implementation EI1, except for the presence of the magnet and the upper end position of the magnet that were modified as illustrated in Table 1. The measurement results for the exemplary implementations EI2 through EI4 and the comparative example CE1 are also illustrated in Table 1.

TABLE 1

| | Presence | Upper End Position of | Amount of Particles |
|---|---|---|---|
| | of Magnet | Magnet | (Relative Value) |
| EI1 | Yes | ½ Diameter of | 5 |
| | | Rotating Member Lower | |
| | | Than Contact Position | |
| EI2 | Yes | ⅓ Diameter of | 20 |
| | | Rotating Member Lower | |
| | | Than Contact Position | |
| EI3 | Yes | Upper End of Rotating | 50 |
| | | Member (i.e. Contact | |
| | | Position) | |
| EI4 | Yes | ⅔ Diameter of | 30 |
| | | Rotating Member Lower | |
| | | Than Contact Position | |
| CE1 | No | N/A | 300 |

From Table 1, it was confirmed that the amount of particles is significantly reduced for the exemplary implementations EI1 through EI4 when compared to the comparative example CE1. Hence, it may be regarded that the film forming apparatus can effectively eliminate the dust that becomes the source or cause of the contamination of the product that is subjected to the film forming process, by providing the magnet around the rotating member.

According to the present disclosure, it is possible to provide a film forming apparatus that can reduce the generation of dust at a transport mechanism.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A film forming apparatus comprising:
a plurality of chambers configured to perform a film forming process;
a carrier configured to hold a substrate to be subjected to the film forming process in the plurality of chambers; and
a transport mechanism configured to successively transport the carrier through the plurality of chambers, wherein
the carrier includes a support surface configured to support the carrier from below when transporting the carrier,
the support surface is provided parallel to the transport direction,
the plurality of chambers include a plurality of rotating members, provided parallel to the transport direction, and configured to make contact with the support surface when transporting the carrier,
the plurality of rotating members are made of a magnetic material, and
a magnet is provided around each of the plurality of rotating members.

2. The film forming apparatus as claimed in claim 1, wherein an upper end of the magnet is located at a position lower than an uppermost portion of each of the plurality of rotating members by a distance corresponding to ⅓ of a diameter of each of the plurality of rotating members or greater.

3. The film forming apparatus as claimed in claim 1, further comprising:
a rotation unit provided with the plurality of rotating members arranged in a line in a direction parallel to the transport direction, and a magnet unit including the magnet.

4. The film forming apparatus as claimed in claim 3, wherein the magnet unit includes a nonmagnetic material, and one or more magnets attached to the rotation unit via the nonmagnetic material.
